(19) United States
(12) Patent Application Publication
(10) Pub. No.: US 2026/0344413 A1
(43) Pub. Date: Oct. 29, 2026

(54) INTEGRATED CAPACITOR AND METHOD OF MANUFACTURING THE SAME

(71) Applicant: Taiwan Semiconductor Manufacturing Company, Ltd., Hsinchu (TW)

(72) Inventors: Chieh-En Chen, Tainan City (TW); Chen-Hsien Lin, Tainan City (TW); Shyh-Fann Ting, Tainan City (TW)

(21) Appl. No.: 19/191,534

(22) Filed: Apr. 28, 2025

(51) Int. Cl. H10W 20/40; H04N 25/616; H10F 39/00

(52) U.S. Cl. CPC H10W 20/496; H10F 39/811; H04N 25/616

(57) ABSTRACT

In some embodiments, the present disclosure relates to an integrated device, including: a first top electrode comprising a base portion extending over a substrate with a first width in a first direction and a first height in a second direction perpendicular to the first direction, wherein the first width is greater than the first height, and a plurality of protrusions extending beneath the base portion, the plurality of protrusions having a second width in the first direction and a second height in the second direction, wherein the second height is greater than the second width; a first bottom electrode surrounding a first protrusion of the plurality of protrusions; a second bottom electrode surrounding a second protrusion of the plurality of protrusions; and a dielectric layer separating the first bottom electrode from the first top electrode and separating the second bottom electrode from the first top electrode.

### BACKGROUND

Integrated devices include a plurality of active and passive components. Passive components include resistors, capacitors, and inductors. Capacitors store charge based on their capacitance. Capacitance is a function of a surface area of a top electrode and a bottom electrode, the relative permeability of the material extending between the top electrode and the bottom electrodes, and the distance between the top electrode and the bottom electrode.

### BRIEF DESCRIPTION OF THE DRAWINGS

Aspects of the present disclosure are best understood from the following detailed description when read with the accompanying figures. The figures are drawn to clearly illustrate relevant aspects of the embodiments. The figures may illustrate relationships between various structures and/or elements within the embodiments. It is noted that the figures are not necessarily drawn to scale. In some instances, the dimensions of the various features may be arbitrarily increased or reduced for clarity of discussion.

FIG. 1 illustrates a cross-sectional view of some embodiments of an integrated device having a plurality of capacitors comprising a shared top electrode and multiple bottom electrodes surrounding protrusions of the shared top electrode.

FIG. 2 illustrates a cross-sectional view of some embodiments of an integrated device having four capacitors comprising the shared top electrode and four bottom electrodes surrounding protrusions of the shared top electrode.

FIGS. 3A-3B illustrate a circuit diagram and a cross-sectional view of embodiments of an integrated device having a first capacitor, a second capacitor, and a third capacitor comprising the shared top electrode in a multiple conversion gain circuit.

FIGS. 4A-4B illustrate a circuit diagram and a cross-sectional view of embodiments of an integrated device having a first capacitor, a second capacitor, a third capacitor, and a fourth capacitor comprising the shared top electrode in a correlated double sampling circuit.

FIGS. 5A-5B illustrate a circuit diagram and a cross-sectional view of embodiments of an integrated device having a first capacitor, a second capacitor, a third capacitor, and a fourth capacitor comprising the shared top electrode as part of a lateral overflow integration capacitor (LOFIC) sampling circuit for four pixel circuits.

FIGS. 6A and 6B illustrate a cross-sectional view and a top down view of some embodiments of an integrated device having a plurality of capacitors comprising a first shared top electrode, a second shared top electrode, a first plurality of bottom electrodes, a second plurality of bottom electrodes, a first floating ring surrounding the first plurality of bottom electrodes, and a second floating ring surrounding the second plurality of bottom electrodes.

FIGS. 7-19 illustrate cross-sectional views of some embodiments of a method of forming an integrated device having a first plurality of capacitors comprising the shared top electrode.

FIG. 20 illustrates a flow diagram of some embodiments of a method of forming an integrated device having a first plurality of capacitors comprising the shared top electrode.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. In some embodiments, the terms “approximately” and/or “about” can be interpreted as meaning +/−10% or +/−5%, while in other embodiments, the terms “approximately” and/or “about” can be interpreted as meaning within the normal fabrication tolerances of a given fab manufacturing flow.

Capacitors are used in a wide variety of integrated devices, including image sensors, memory arrays, power control circuits, and more. Capacitors comprise a first electrode and a second electrode separated by a dielectric layer. Factors in the selection of a capacitor for different uses include the capacitance, size, and breakdown voltage of the capacitor. In image sensor circuits, capacitors have a variety of applications, some examples including lateral overflow integration capacitor (LOFIC) sampling circuits to improve the dynamic range of the resulting image, altering the conversion gain of the image sensor for dynamic range improvements, increasing charge retention during read processes to reduce noise, and in correlated double sampling circuits to eliminate reset noise.

As image sensor technology develops, the ongoing goal of increased image resolution results in reduced pixel sizes being desirable. However, one of the factors that determine the capacitance of a capacitor is the surface area of the top and bottom electrodes. Further, including a plurality of capacitors within image sensor circuits to improve performance results in greater space being used to house the capacitors, thereby increasing the size of the pixels. The increase in pixel size from including capacitors is due to the capacitors'own size (e.g., the lateral area taken by the capacitors) and the design rules (e.g., the space between the capacitors maintained to reduce device manufacturing failure and improve yield rates) for placement of capacitors within the integrated circuit. Therefore, an integrated device that reduces the footprint (e.g., the total lateral area used by a component) of the capacitors without removing them is desirable for an image sensor with greater resolution, dynamic range, and reduce noise.

In the present disclosure plurality of capacitors with a shared top electrode are presented. The shared top electrode has a first protrusion and a second protrusion. A first bottom electrode surrounds the first protrusion and is coupled to a first wire beneath the capacitors. A second bottom electrode surrounds the second protrusion and is coupled to a second wire beneath the capacitors. The first bottom electrode and the second bottom electrode are isolated from one another by an interlayer dielectric. Using the shared top electrode eliminates the design rule spacing that would be between multiple separate capacitors. Further, the subsets of the plurality of capacitors can be combined by coupling the bottom electrodes together through the first wire or the second wire, resulting in a plurality of capacitors that may have differing capacitances in a reduced area compared to embodiments with separated top electrodes.

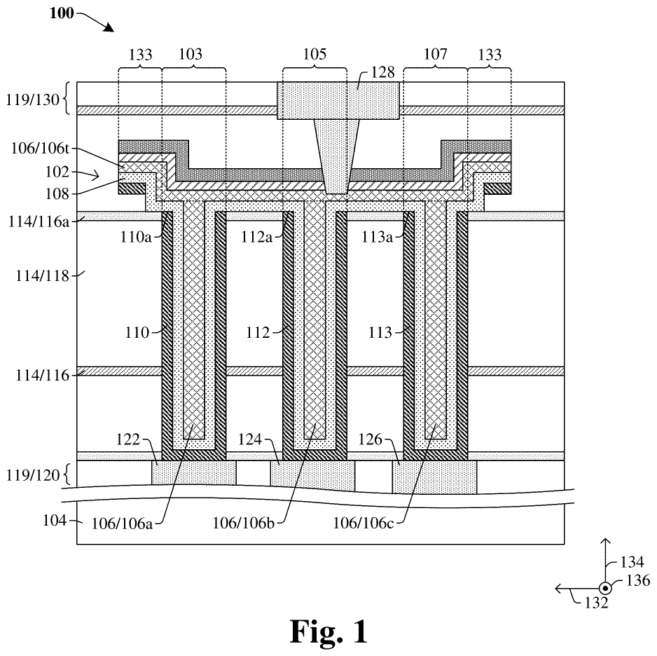

FIG. 1 illustrates a cross-sectional view 100 of some embodiments of an integrated device having a plurality of capacitors comprising a shared top electrode and multiple bottom electrodes surrounding protrusions of the shared top electrode.

A first plurality of capacitors 102 overlies a substrate 104. The first plurality of capacitors 102 comprises a first shared top electrode 106, a first dielectric 108, a first bottom electrode 110, and a second bottom electrode 112. The first dielectric 108 separates the first shared top electrode 106 from the first bottom electrode 110 and the second bottom electrode 112. The first shared top electrode 106 comprises a base portion 106t overlying the first bottom electrode 110 and the second bottom electrode 112, a first protrusion 106a extending between inner sidewalls of the first bottom electrode 110, and a second protrusion 106b extending between inner sidewalls of the second bottom electrode 112. The first bottom electrode 110, the first dielectric 108, and the first protrusion 106a of the first shared top electrode 106 together make up a first capacitor 103. The second bottom electrode 112, the first dielectric 108, and the second protrusion 106b of the first shared top electrode 106 together make up a second capacitor 105. In some embodiments, the first shared top electrode 106 further comprises a third protrusion 106c extending between inner sidewalls of a third bottom electrode 113. In further embodiments, the third bottom electrode 113, the first dielectric 108, and the third protrusion 106c of the first shared top electrode 106 together make up a third capacitor 107.

The first bottom electrode 110 is electrically insulated from the second bottom electrode 112 by an interlayer dielectric 114. The interlayer dielectric 114 comprises a plurality of etch stop layers 116 extending between a first plurality of insulative layers 118. A first etch stop layer 116a of the plurality of etch stop layers 116 extends between a first upper surface 110a of the first bottom electrode 110 and a second upper surface 112a of the second bottom electrode 112. In some embodiments, the first etch stop layer 116a extends between the second upper surface 112a of the second bottom electrode 112 and a third upper surface 113a of the third bottom electrode 113.

A first wire level 120 of an interconnect structure 119 extends beneath the first plurality of capacitors 102. A first wire 122 of the first wire level 120 is electrically coupled to the first bottom electrode 110, and a second wire of the first wire level 120 is electrically coupled to the second bottom electrode 112. In some embodiments, a third wire 126 of the first wire level 120 is electrically coupled to the third bottom electrode 113. In other embodiments, the third bottom electrode is electrically coupled to the first wire 122 and/or the second wire 124. A first upper wire 128 of an upper wire level 130 of the interconnect structure 119 is electrically coupled to the first shared top electrode 106.

The first plurality of capacitors 102 having the first shared top electrode 106 do not have design rule spacing between them, as they are formed from the same electrical component. The configuration further reduces the footprint of the first plurality of capacitors 102 compared to embodiments with separate capacitors by eliminating the lateral area taken by peripheral portions 133 of capacitors that extend between the separate capacitors. Instead, peripheral portions 133 of the first plurality of capacitors 102 having the first shared top electrode 106 form a continuous ring around the first capacitor 103 and the second capacitor 105. The elimination of the design rule spacing and the area of the peripheral portions 133 reduces the total footprint of the first plurality of capacitors 102 in embodiments where the capacitors are coupled to the same node (e.g., a controlled voltage, ground, or another node in an integrated circuit) while maintaining independent functionality, thereby offering the increased dynamic range and reduced noise of image sensors utilizing correlated double sampling circuits, LOFIC circuits, charge retention capacitors, sensors with multiple conversion gain settings, or the like with a reduced lateral footprint. The reduced lateral footprint results in greater flexibility in the integrated circuit layout, providing an opportunity to further reduce the pixel size and increase the resolution of pixel sensor arrays utilizing correlated double sampling circuits, LOFIC circuits, charge retention capacitors, or the like.

In some embodiments, the base portion 106t of the first shared top electrode 106 has a first width in a first direction 132 and a first height in a second direction 134 perpendicular to the first direction 132, wherein the first width is greater than the first height. In further embodiments, the plurality of protrusions (e.g., the first protrusion 106a, the second protrusion 106b, and the third protrusion 106c) have a second width in the first direction 132 and a second height in the second direction 134, wherein the second height is greater than the second width. The first bottom electrode 110 surrounds the first protrusion 106a in the first direction 132 and a third direction 136 perpendicular to the first direction 132 and the second direction 134; a second bottom electrode 112 surrounding a second protrusion 106b in the first direction 132 and the third direction 136. In some embodiments, the third bottom electrode 113 surrounds a third protrusion 106c in the first direction 132 and the third direction 136. The first direction 132 and the third direction 136 are approximately parallel to the upper surfaces of the first, second, and third wires 122, 124, 126, and the second direction 134 is approximately normal to the upper surfaces of the first, second, and third wires 122, 124, 126.

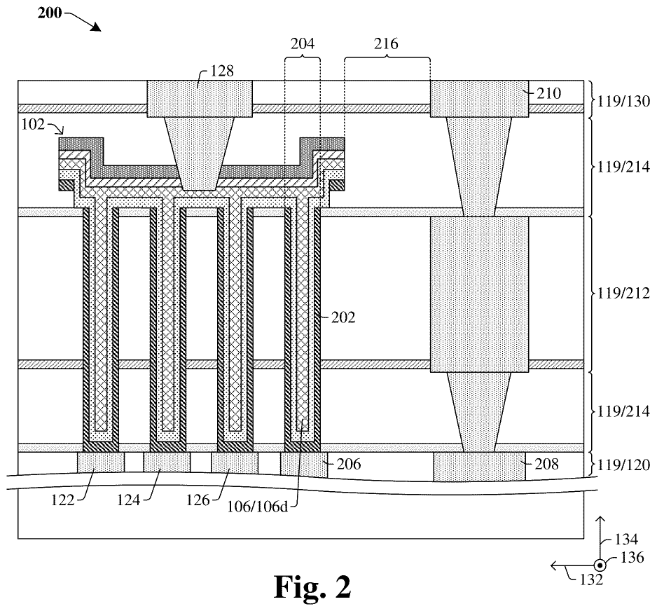

FIG. 2 illustrates a cross-sectional view 200 of some embodiments of an integrated device having four capacitors comprising the shared top electrode and four bottom electrodes surrounding protrusions of the shared top electrode.

In some embodiments, the first shared top electrode 106 further comprises a fourth protrusion 106d extending between inner sidewalls of a fourth bottom electrode 202. In further embodiments, the fourth bottom electrode 202, the first dielectric 108, and the fourth protrusion 106d of the first shared top electrode 106 together make up a fourth capacitor 204. In some embodiments, a fourth wire 206 of the first wire level 120 is electrically coupled to the fourth bottom electrode 202. In other embodiments, the fourth bottom electrode 202 is electrically coupled to one of the first wire 122, the second wire 124, or the third wire 126. The fourth bottom electrode 202 surrounds the fourth protrusion 106d in the first direction 132 and the third direction 136.

In some embodiments, a fifth wire 208 of the first wire level 120 is coupled electrically coupled to a second upper wire 210 of the upper wire level 130 by one or more intermediate wire levels 212 and/or one or more intermediate via levels 214 of the interconnect structure 119. In some embodiments, the fifth wire 208 is electrically coupled to one or more of the first wire 122, the second wire 124, the third wire 126, and the fourth wire 206. In other embodiments, the second upper wire 210 is electrically coupled to the first upper wire 128. The first plurality of capacitors 102 are spaced from wires and vias of the one or more intermediate wire levels 212 and/or one or more intermediate via levels 214 by a first design rule spacing 216 to reduce loss of performance or device failure that may occur due to leakage between the first plurality of capacitors 102 and the interconnect structure 119.

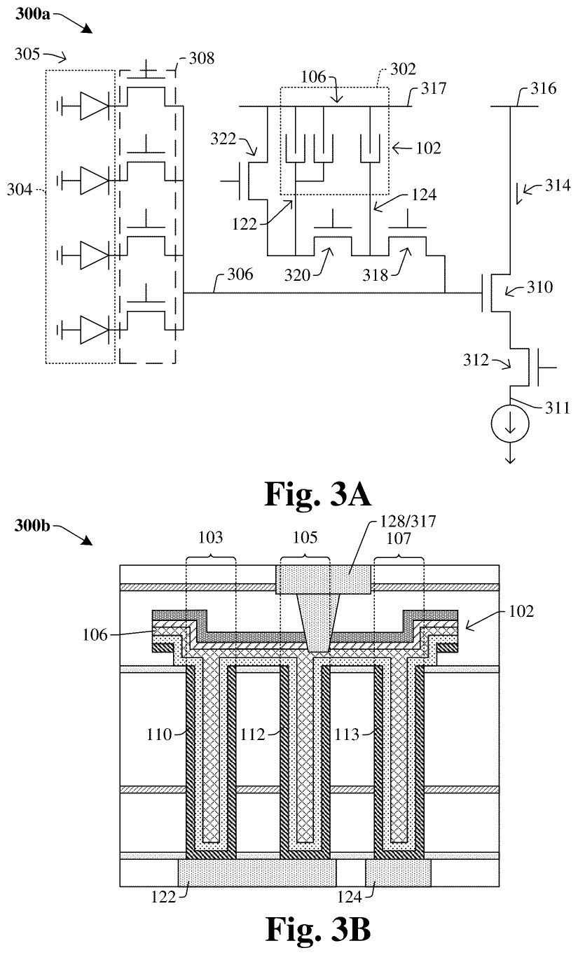

FIGS. 3A-3B illustrate a circuit diagram 300a and a cross-sectional view 300b of embodiments of an integrated device having a first capacitor, a second capacitor, and a third capacitor comprising the shared top electrode in a multiple conversion gain circuit. The cross-sectional view 300b of FIG. 3B corresponds to a portion 302 of the circuit diagram 300a of FIG. 3A. FIG. 3A and FIG. 3B are described concurrently.

A pixel circuit 305 comprises a plurality of photodetectors 304 that are arranged in an array. The plurality of photodetectors 304 are coupled to a floating diffusion region 306 by a plurality of transfer transistors 308 extending between the plurality of photodetectors 304 and the floating diffusion region 306. The floating diffusion region 306 is coupled to a gate of a source follower transistor 310. The source follower transistor 310 is coupled in series to a row select transistor 312 and an output line 311.

When electromagnetic radiation enters the plurality of photodetectors 304, it is transduced into a charge held within individual photodetectors. The volume of charge held within the individual photodetectors is based on the intensity and spectrum of the light entering the plurality of photodetectors 304, in addition to colors filters covering the individual photodetectors. When a transfer transistor of the plurality of transfer transistors 308 is closed, the charge held by a corresponding photodetector (e.g., the individual photodetector coupled to the transfer transistor) of the plurality of photodetectors 304 is transferred to the floating diffusion region 306. The transferred charge at the floating diffusion region 306 raises a voltage at the gate of the source follower transistor 310. When the row select transistor 312 is closed, a current 314 passes through the source follower transistor 310 and the row select transistor 312 from a first voltage rail 316 (e.g., a conductive wire held at a voltage that is substantially constant during operation) to the output line 311. The amplitude of the current 314 passing through the source follower transistor is affected by the voltage at the gate of the source follower transistor 310.

The voltage at the gate of the source follower transistor 310 is dependent on the transferred charge from the corresponding photodetector and the capacitance at the floating diffusion region 306. A higher capacitance at the floating diffusion region 306 with the same amount of charge held results in a lower voltage at the gate of the source follower transistor 310. The lower voltage results in a reduced current 314 passing through the source follower transistor 310. That is, increasing the capacitance at the floating diffusion region 306 reduces the conversion gain of the pixel circuit, such that the same difference in the magnitude of charge at the gate of the source follower transistor 310 results in a lower change in the amplitude of the current 314.

A low conversion gain configuration (e.g., increasing the capacitance at the floating diffusion region) improves the responsiveness of the pixel circuit to differences in comparatively large amounts of charge, such as those accumulated by the photodetector in areas with a high amount of electromagnetic radiation (for example, bright areas). Meanwhile, a high conversion gain configuration (e.g., decreasing the capacitance at the floating diffusion region) improves the responsiveness of the pixel circuit to differences in comparatively small amounts of charge, such as those accumulated by the photodetector in areas with a low amount of electromagnetic radiation (for example, dark areas). Collecting the response of the pixel circuit to a charge with different conversion gain configurations and processing the resulting signals is used to capture images with a higher dynamic range.

To collect the response of the pixel circuit to a charge with three or more different conversion gain configurations, the first plurality of capacitors 102 are used. The first shared top electrode 106 is coupled to the first voltage rail 316 or a second voltage rail 317 held at a substantially constant reference voltage during operation. The first bottom electrode 110 and the third bottom electrode 113 are electrically coupled to the first wire 122. The second bottom electrode 112 is electrically coupled to the second wire 124. In some embodiments, the length of the first, second and third bottom electrodes 110, 112, 113 (and therefore the surface area of the first, second, and third capacitors 103, 105, 107) is chosen to result in dynamic ranges that are adjacent or partially overlapping.

The second wire 124 is coupled to the floating diffusion region 306 by a medium conversion gain (MCG) transistor 318 (e.g., a first source/drain region of the MCG transistor 318 is coupled to the second wire 124 and a second source/drain region of the MCG transistor 318 is coupled to the floating diffusion region 306). The first wire 122 is coupled to the second wire 124 by a low conversion gain (LCG) transistor 320 (e.g., a third source/drain region of the MCG transistor 318 is coupled to the second wire 124 and a fourth source/drain region of the MCG transistor 318 is coupled to the floating diffusion region 306). The conversion gain of the pixel circuit 305 is controlled by the activation of the MCG transistor 318 and the LCG transistor 320.

When a response of the pixel circuit with a medium conversion gain configuration is desired, the MCG transistor 318 is closed, coupling the third capacitor 107 to the floating diffusion region 306, thereby increasing the capacitance at the floating diffusion region 306 and reducing the conversion gain. When a response of the pixel circuit with a low conversion gain configuration is desired, the MCG transistor 318 and the LCG transistor 320 are closed, coupling the first capacitor 103, the second capacitor 105, and the third capacitor 107 to the floating diffusion region 306, further increasing the capacitance at the floating diffusion region 306 and reducing the conversion gain. In other embodiments, the MCG transistor 318 and the LCG transistor 320 are coupled in parallel, and may be closed separately or in combination to result in the floating diffusion region having more different conversion gain configurations.

A reset transistor 322 is coupled between one of the floating diffusion region 306, the first wire 122, or the second wire 124, and the second voltage rail 317 held at the reference voltage during operation. After the signals from the plurality of photodetectors 304 have been read at the desired conversion gain configurations, the reset transistor 322 is closed, coupling the floating diffusion region 306 and the first, second and third bottom electrodes 110, 112, 113 to the second voltage rail 317 and setting the voltage at the floating diffusion region 306 to the reference voltage of the second voltage rail 317.

In this configuration, using the first, second, and third capacitor 103, 105, 107 having the first shared top electrode 106 results in the first plurality of capacitors 102 having a smaller footprint than embodiments comprising multiple separate capacitors of approximately the same capacitances and extending to approximately the same depth as the first plurality of capacitors 102.

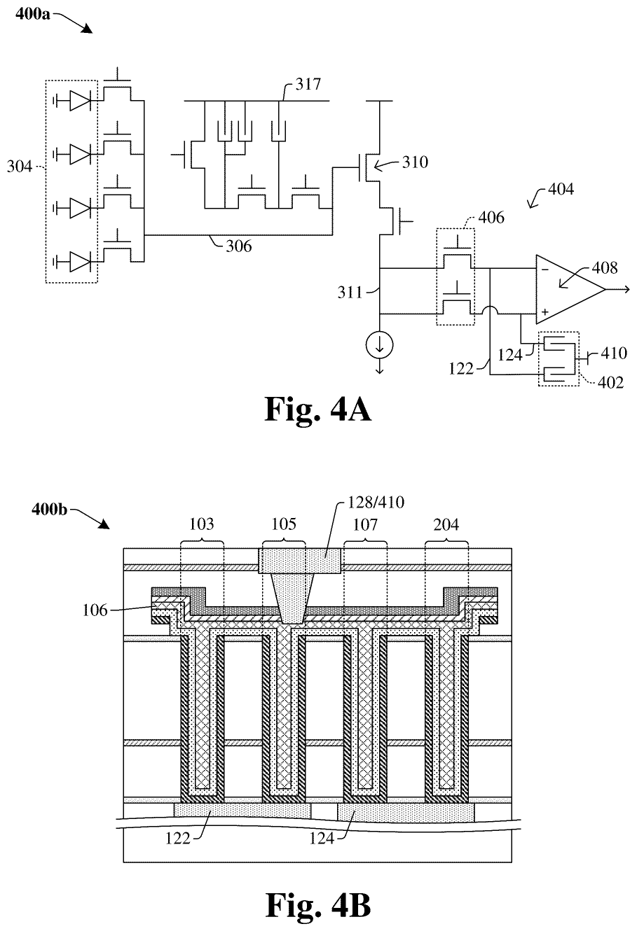

FIGS. 4A-4B illustrate a circuit diagram 400a and a cross-sectional view 400b of embodiments of an integrated device having a first capacitor, a second capacitor, a third capacitor, and a fourth capacitor comprising the shared top electrode in a correlated double sampling circuit. The cross-sectional view 400b of FIG. 4B corresponds to a portion 402 of the circuit diagram 400a of FIG. 4A. FIG. 4A and FIG. 4B are described concurrently.

A correlated double sampling circuit 404 uses sampling transistors 406, a comparator 408, and a plurality of capacitors with substantially the same capacitance. The correlated double sampling circuit 404 captures a reference signal received from the pixel circuit when the floating diffusion region 306 is set to the reference voltage. The correlated double sampling circuit 404 then compares the reference signal to the output signal received from the pixel circuit when the floating diffusion region holds a charge form one of the plurality of photodetectors 304. The correlated double sampling circuit 404 removes the reference signal from the output signal, removing variations resulting from thermal noise at the capacitor from the output signal.

The reference signal is captured by a first sampling transistor of the sampling transistors 406 coupled to the first wire 122 and a first input to the comparator 408. The output signal is captured by a second sampling transistor of the sampling transistors 406 coupled to the second wire 124 and a second input to the comparator 408. In some embodiments, the first capacitor 103 and the second capacitor 105 are coupled to the first wire 122 and the third capacitor 107 and the fourth capacitor 204 are coupled to the second wire 124. In other embodiments, the first capacitor 103 is coupled to the first wire 122 and the second capacitor 105 is coupled to the second wire 124. The first shared top electrode 106 is coupled to a reference voltage line such as, for example, the second voltage rail 317, or a third voltage rail 410 held at a different substantially constant voltage during operation.

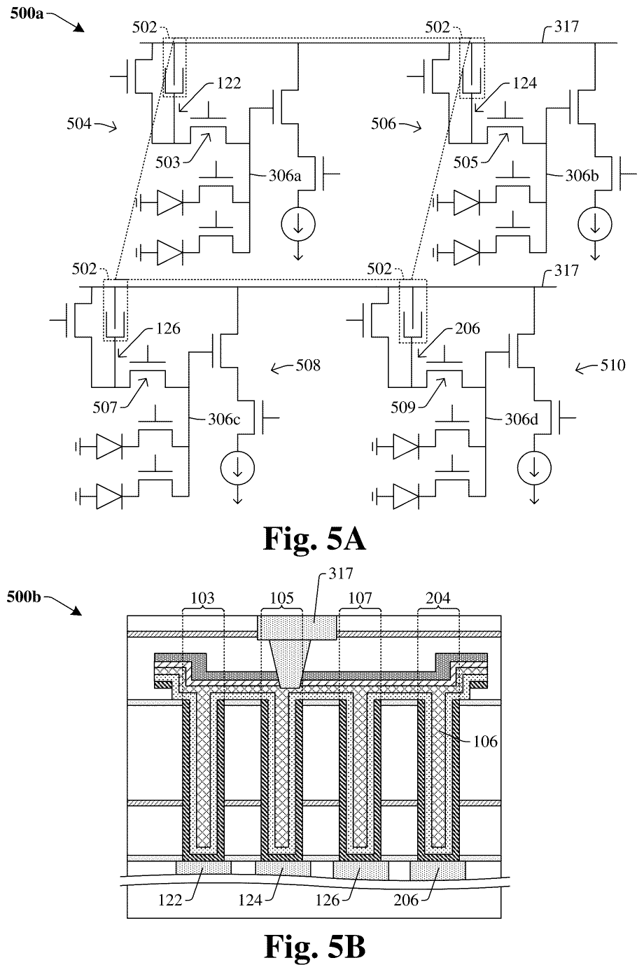

FIGS. 5A-5B illustrate a circuit diagram 500a and a cross-sectional view 500b of embodiments of an integrated device having a first capacitor, a second capacitor, a third capacitor, and a fourth capacitor comprising the shared top electrode as part of a lateral overflow integration capacitor (LOFIC) sampling circuit for four pixel circuit circuits. The cross-sectional view 500b of FIG. 5B corresponds to a portions 502 of the circuit diagram 500a of FIG. 5A. FIG. 5A and FIG. 5B are described concurrently.

In some embodiments, the first plurality of capacitors 102 are used in multiple separate pixel circuits, as part of multiple conversion gain circuitry, LOFIC circuitry, or the like. LOFIC sampling circuits alter the capacitance at the floating diffusion regions of pixel circuits to alter the conversion gain of the pixel circuits. LOFIC sampling circuits are configured to have charge overflow from the photodetectors to the floating diffusion region and/or the capacitors during the exposure of the photodetector, extending the dynamic range by incorporating the overflow charge into the sampling process. Samples taken with different conversion gains are used to detect the variation in images at different light levels, increasing the dynamic range of the final image.

In some embodiments, the first wire 122 is coupled to the first capacitor 103. The first wire 122 is further coupled to a first floating diffusion region 306a by a first LOFIC transistor 503 in a first pixel circuit 504 (e.g., a first source/drain region of the first LOFIC transistor 503 is coupled to the first wire 122 and a second source/drain region of the first LOFIC transistor 503 is coupled to the first floating diffusion region 306a). The second wire 124 is coupled to the second capacitor 105. The second wire 124 is further coupled to a second floating diffusion region 306b by a second LOFIC transistor 505 in a second pixel circuit 506 (e.g., a first source/drain region of the second LOFIC transistor 505 is coupled to the first wire 122 and a second source/drain region of the second LOFIC transistor 505 is coupled to the second floating diffusion region 306b). The third wire 126 is coupled to the third capacitor 107. The third wire 126 is further coupled to a third floating diffusion region 306c by a third LOFIC transistor 507 in a third pixel circuit 508 (e.g., a first source/drain region of the third LOFIC transistor 507 is coupled to the third wire 126 and a second source/drain region of the third LOFIC transistor 507 is coupled to the third floating diffusion region 306c). The fourth wire 206 is coupled to the fourth capacitor 204. The fourth wire 206 is further coupled to a fourth floating diffusion region 306d by a fourth LOFIC transistor 509 in a fourth pixel circuit 510 (e.g., a first source/drain region of the fourth LOFIC transistor 509 is coupled to the fourth wire 206 and a second source/drain region of the fourth LOFIC transistor 509 is coupled to the fourth floating diffusion region 306d). The first shared top electrode 106 is coupled to the second voltage rail 317.

The consolidation of the first plurality of capacitors 102 into one component reduces the footprint of the first plurality of capacitors 102 while maintaining the benefits of a LOFIC sampling circuit integrated into the first, second, third, and fourth pixel circuits 504, 506, 508, 510.

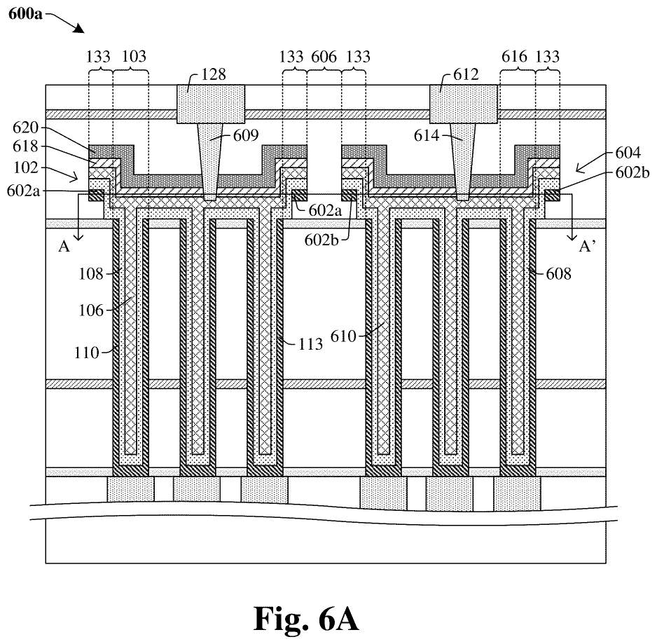

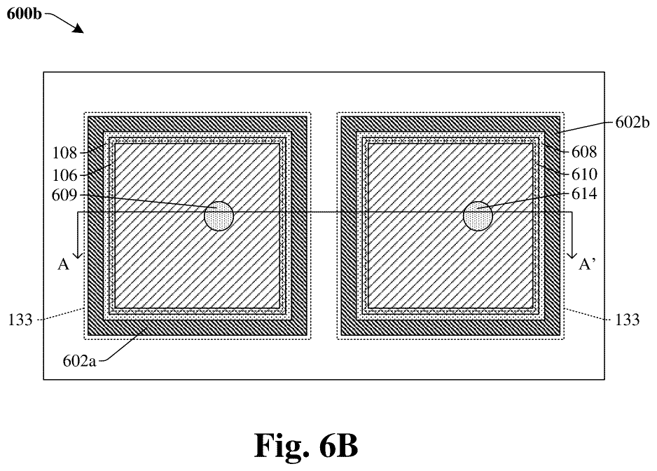

FIGS. 6A and 6B illustrate a cross-sectional view and a top down view of some embodiments of an integrated device having a plurality of capacitors comprising a first shared top electrode, a second shared top electrode, a first plurality of bottom electrodes, a second plurality of bottom electrodes, a first floating ring surrounding the first plurality of bottom electrodes, and a second floating ring surrounding the second plurality of bottom electrodes. The cross-sectional view 600a of FIG. 6A is taken along line A-A′ of the top down view 600b of FIG. 6B. FIG. 6A and FIG. 6B are described concurrently.

In some embodiments, the first plurality of capacitors 102 is spaced from a second plurality of capacitors 604 by a second design rule spacing 606. The first plurality of capacitors 102 is surrounded by a first peripheral portion 132a with a first floating conductive ring 602a. The second plurality of capacitors 604 is surrounded by a second peripheral portion 132b with a second floating conductive ring 602b. The first floating conductive ring 602a is electrically isolated from bottom electrodes of the first plurality of capacitors 102 by the first dielectric 108. The second floating conductive ring 602b is electrically isolated from bottom electrodes of the second plurality of capacitors 604 by a second dielectric layer 608. The isolation of the first floating conductive ring 602a and the second floating conductive ring 602b substantially eliminates leakage between the bottom electrodes of the first plurality of capacitors 102 and bottom electrodes of the second plurality of capacitors 604. In some embodiments, the first floating conductive ring 602a is spaced from the first bottom electrode 110 and the second bottom electrode 112 in a direction normal to a bottom surface of the first floating conductive ring 602a.

In some embodiments, the first shared top electrode 106 is coupled to the first upper wire 128 by a first via 609, and a second shared top electrode 610 of the second plurality of capacitors 604 is electrically coupled to the second upper wire 210 and/or a third upper wire 612 by a second via 614. In some embodiments, a first capping layer 618 overlies and covers upper surfaces of the first shared top electrode 106, and a second capping layer 620 overlies and covers upper surfaces of the first capping layer 618. The first via 609 passes through both the first capping layer 618 and the second capping layer 620.

The first shared top electrode 106 is electrically coupled to a first node of an integrated circuit and the second shared top electrode 610 is coupled to a second node of the integrated circuit. As only one second design rule spacing 606 and two peripheral portions 133 extend between a first capacitor 103 of the first plurality of capacitors 102 and a furthest capacitor 616 of the second plurality of capacitors 604, the lateral footprint of the first plurality of capacitors 102 and the second plurality of capacitors 604 is greatly reduced compared to embodiments with separate top electrodes, peripheral portions, and design rule spacings for the capacitors. The reduced lateral footprint results in more flexibility of design and increased opportunity for higher resolution image sensors.

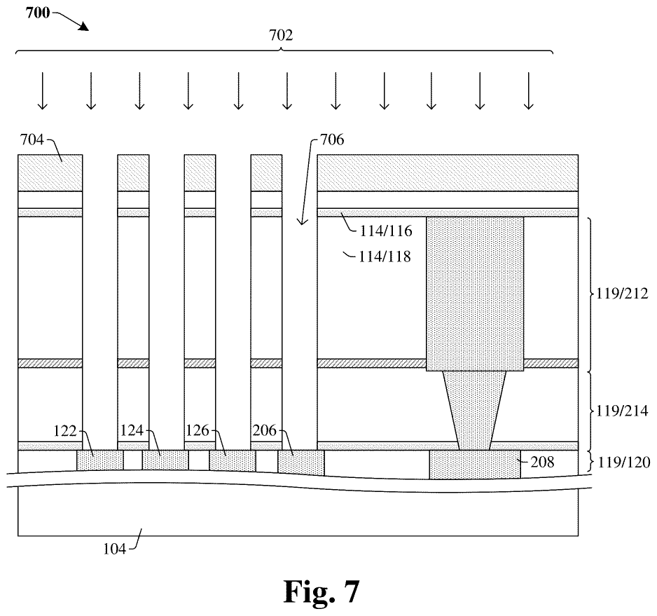

FIGS. 7-19 illustrate cross-sectional views of some embodiments 700-1900 of a method of forming an integrated device having a first plurality of capacitors comprising the shared top electrode. Although FIGS. 7-19 are described in relation to a method, it will be appreciated that the structures disclosed in FIGS. 7-19 are not limited to such a method, but instead may stand alone as structures independent of the method.

As shown in cross-sectional view 700 of FIG. 7, a first portion of the interconnect structure 119 is formed over the substrate 104. The first portion of the interconnect structure 119 comprises the first wire level 120, the one or more intermediate wire levels 212, and the one or more via levels 214. The first wire level 120 comprises the first wire 122 and the second wire 124. In some embodiments, the first wire level 120 further comprises the third wire 126, the fourth wire 206, and the fifth wire 208. In some embodiments, the interconnect structure 119 is formed by alternating between depositing layers of the interlayer dielectric 114 (comprising the first plurality of insulative layers 118 and the plurality of etch stop layers 116) and performing one or more damascene and/or dual damascene processes to form the first wire level 120, the one or more intermediate wire levels 212, and the one or more via levels 214.

In some embodiments, the first wire level 120, the one or more intermediate wire levels 212, and the one or more via levels 214 are or comprise a conductive material, such as such as copper (Cu), tungsten (W), aluminum (Al), or the like. In some embodiments, the first plurality of insulative layers 118 are or comprise an insulative material such as silicon dioxide (SiO₂) or the like. In some embodiments, the plurality of etch stop layers 116 independently are or comprise an insulative material such as silicon carbide (SiC), silicon nitride (Si₃N₄), or the like.

After the first portion of the interconnect structure 119 is formed over the substrate 104, a first masking layer 704 is formed over the interlayer dielectric 114. In some embodiments, the first masking layer is or comprises a photoresist or a hard mask and is formed using a dipping process, spin on process, deposition process, or another similar process. The first masking layer 704 is then patterned. In some embodiments, the first masking layer 704 is patterned using photolithography. The patterning of the first masking layer 704 is performed to expose portions of the interlayer dielectric 114 extending over the first wire 122 and the second wire 124.

After the patterning of the first masking layer 704, a first etching process 702 is performed. The first etching process 702 removes portions of the interlayer dielectric 114 overlying the first wire 122 and the second wire 124 and exposed by the first masking layer 704, forming a first plurality of trenches 706. The first etching process 702 exposes the first wire 122 and the second wire 124. In some embodiments, the first etching process 702 is or comprises an anisotropic dry etching process. The first masking layer 704 is subsequently removed.

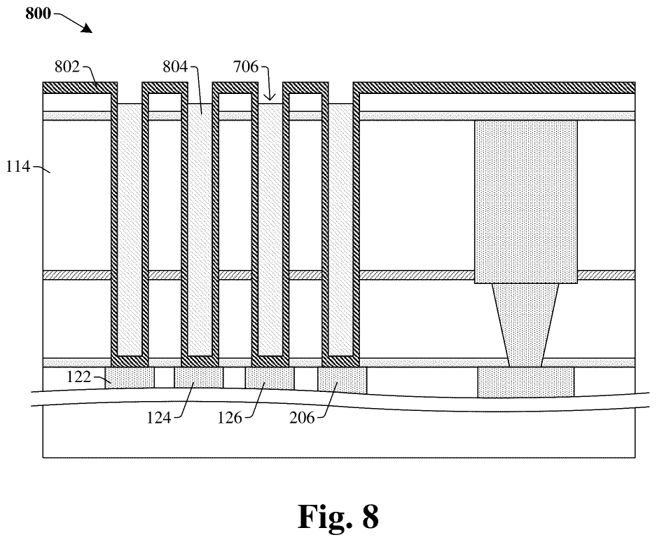

As shown in cross-sectional view 800 of FIG. 8, a first conformal electrode layer 802 is formed over the interlayer dielectric 114 and extends to the first wire 122 and the second wire 124. In some embodiments, the first conformal electrode layer 802 is formed using a deposition process, such as atomic layer deposition (ALD), physical vapor deposition (PVD), chemical vapor deposition (CVD), or the like. In some embodiments, the first conformal electrode layer 802 is or comprises a conductive material, such as such as tantalum (Ta), tantalum nitride (TaN), titanium nitride (TiN), or the like. In some embodiments, the first conformal electrode layer 802 further contacts a third wire 126 and a fourth wire 206.

After the first conformal electrode layer 802 is formed over the interlayer dielectric 114, a plurality of photoresist plugs 804 are formed in the first plurality of trenches 706. In some embodiments, the plurality of photoresist plugs 804 are formed using a spin on, spray on, dipping, or another similar process, and are patterned using one or more of photolithography or an etch back process. The photoresist plugs 804 protect the first plurality of trenches 706 and the underlying portions of the first conformal electrode layer 802 from damage during subsequent etching processes.

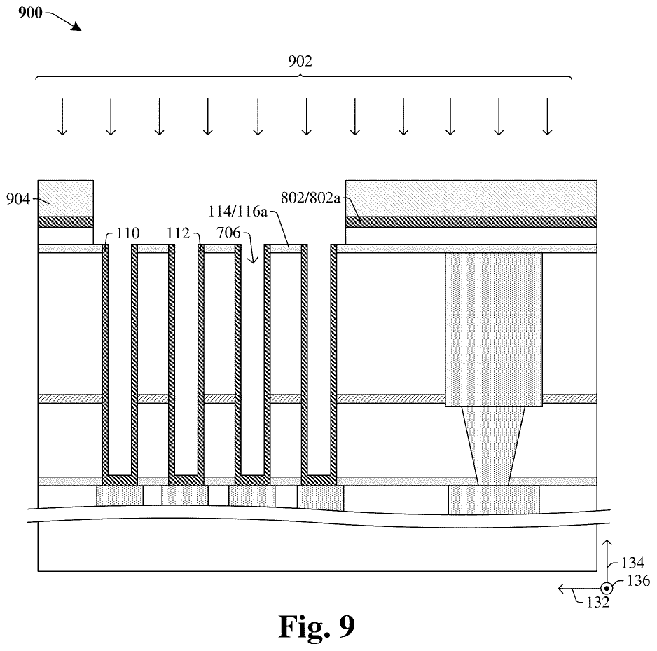

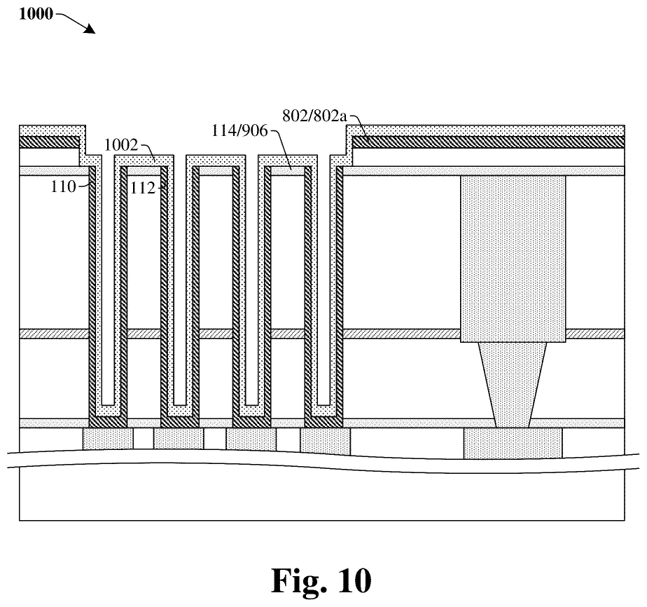

As shown in the cross-sectional view 900 of FIG. 9, a second masking layer 904 is formed over the interlayer dielectric 114. In some embodiments, the second masking layer 904 is or comprises a photoresist or a hard mask and is formed using a dipping process, spin on process, deposition process, or another similar process. The second masking layer 904 is then patterned. In some embodiments, the second masking layer 904 is patterned using photolithography. The patterning of the second masking layer 904 is performed to expose portions of the interlayer dielectric 114 between and surrounding the first plurality of trenches 706. The second masking layer 904 is spaced from the first plurality of trenches 706 in the first direction 132 and the third direction 136.

After the patterning of the second masking layer 904, a second etching process 902 is performed. The second etching process 902 removes portions of first conformal electrode layer 802 and the interlayer dielectric 114 extending between and around the first trenches 706. The second etching process 902 results in the first bottom electrode 110 and the second bottom electrode 112 remaining within the first trenches 706 and being isolated from one another by the interlayer dielectric 114, and an overlying portion 802a of the first conformal electrode layer 802 remaining over the interlayer dielectric 114 and separated from the first bottom electrode 110 and the second bottom electrode 112. In some embodiments, the second etching process 902 stops at a first etch stop layer 906 of the plurality of etch stop layers 116. The first etch stop layer 906 extends between uppermost surfaces of the first bottom electrode 110 and the second bottom electrode 112. In some embodiments, the second etching process 902 is or comprises an anisotropic dry etching process. The second masking layer 904 is subsequently removed, and remaining portions of the plurality of photoresist plugs (see 804 of FIG. 8) are removed using an ashing process or the like.

As shown in cross-sectional view 1000 of FIG. 10, a first conformal dielectric 1002 is formed over the first etch stop layer 906, the overlying portion 802a of the first conformal electrode layer 802, and the first and second bottom electrode 110, 112. In some embodiments, the first conformal dielectric 1002 is formed using a deposition process, such as ALD, PVD, CVD, or the like. In some embodiments, the first conformal dielectric 1002 is or comprises a insulative material with a high dielectric constant (e.g., a dielectric constant greater than silicon dioxide), such as such as hafnium oxide (HfO₂), zirconium oxide (ZrO₂), or the like. In some embodiments, after forming the first conformal dielectric 1002, the first conformal dielectric 1002 directly contacts inner sidewalls of the interlayer dielectric 114.

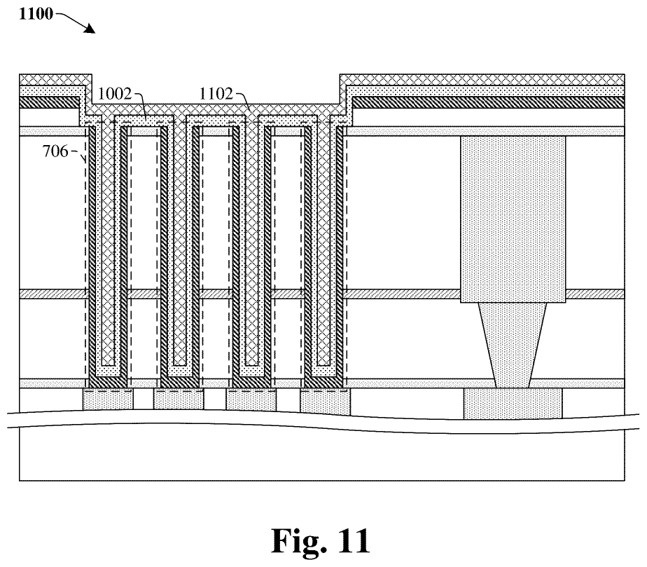

As shown in cross-sectional view 1100 of FIG. 11, a second conformal electrode layer 1102 is formed over the first conformal dielectric 1002, filling the first plurality of trenches 706 (shown in phantom). In some embodiments, the second conformal electrode layer 1102 is formed using a deposition process, such as ALD, PVD, CVD, or the like. In some embodiments, the second conformal electrode layer 1102 is or comprises a conductive material, such as such as tantalum (Ta), tantalum nitride (TaN), titanium nitride (TiN), or the like.

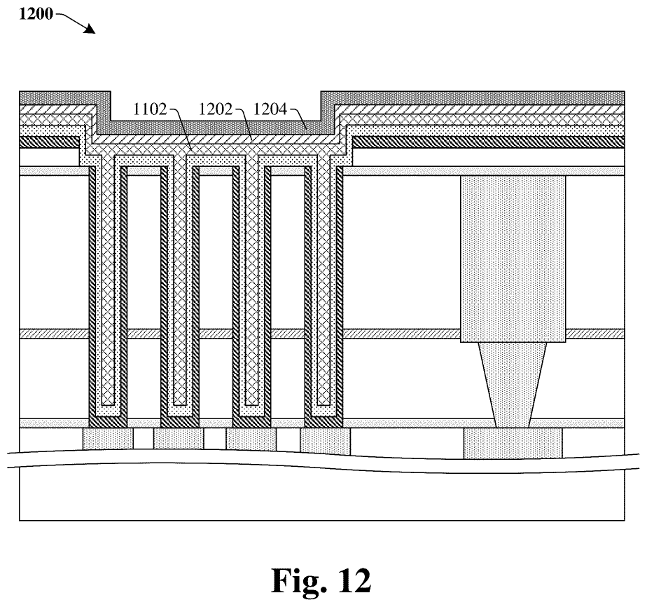

As shown in cross-sectional view 1200 of FIG. 12, a first conformal capping layer 1202 and a second conformal capping layer 1204 are formed over the second conformal electrode layer 1102. In some embodiments, the first conformal capping layer 1202 and a second conformal capping layer 1204 are formed using a deposition process, such as ALD, PVD, CVD, or the like. In some embodiments, the first conformal capping layer 1202 is or comprises an insulative material such as silicon dioxide (SiO₂) or the like. In some embodiments, the second conformal capping layer 1204 is or comprises an insulative material such as silicon nitride (Si₃N₄) or the like.

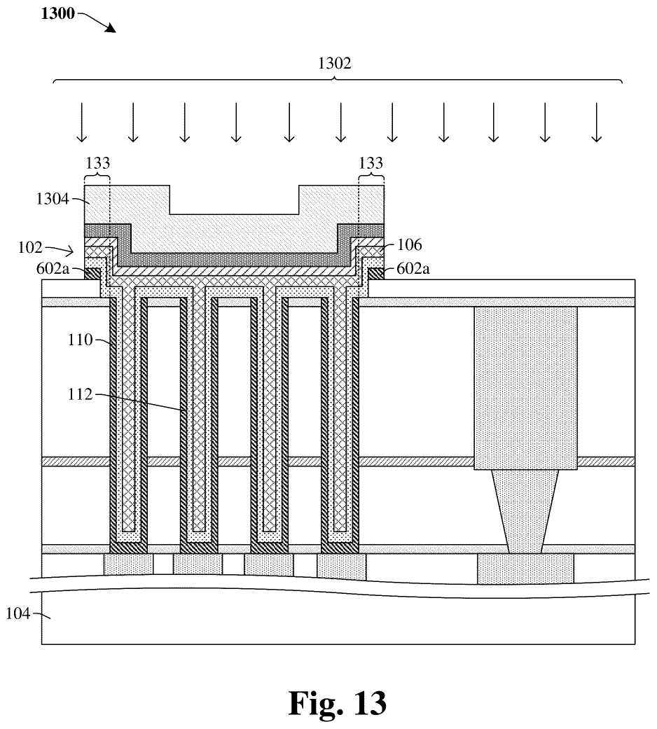

As shown in the cross-sectional view 1300 of FIG. 13, a third masking layer 1304 is formed over the second conformal capping layer (see 1204 of FIG. 12). In some embodiments, the third masking layer 1304 is or comprises a photoresist or a hard mask and is formed using a dipping process, spin on process, deposition process, or another similar process. The third masking layer 1304 is then patterned. In some embodiments, the third masking layer 1304 is patterned using photolithography. The patterning of the third masking layer 1304 is performed to expose portions of the second conformal capping layer (see 1204 of FIG. 12) extending beyond peripheral portions 133 of the first plurality of capacitors 102 to be formed hereafter.

After the patterning of the third masking layer 1304, a third etching process 1302 is performed. The third etching process 1302 removes portions of the overlying portions 802a of the first conformal electrode layer (see 802 of FIG. 8), the first conformal dielectric (see 1002 of FIG. 10), the second conformal electrode layer (see 1102 of FIG. 11), first conformal capping layer (see 1202 of FIG. 12), the second conformal capping layer (see 1204 of FIG. 12) extending beyond peripheral portions 133 of the first plurality of capacitors 102. The third etching process 1302 results in the first plurality of capacitors 102 remaining over the substrate 104, and the first plurality of capacitors 102 being surrounded by the first floating conductive ring 602a. The first capping layer 618 and the second capping layer 620 remain on the first plurality of capacitors 102. In some embodiments, the third etching process 1302 is or comprises an anisotropic dry etching process. The third masking layer 1304 is subsequently removed.

The isolation of the overlying portions (see 802a of FIG. 9) of the first conformal electrode layer (see 802 of FIG. 8) eliminates the use of spacers between the first shared top electrode 106 and the outer sidewalls of the bottom electrodes, as residue from the third etching process cannot couple the first shared top electrode 106 to the first bottom electrode 110 or the second bottom electrode 112. Therefore, performing the second etching process (see 902 of FIG. 9) simplifies the patterning of the first plurality of capacitors 102 during the third etching process 1302 to using a single masking layer 1304, where other embodiments without the second etching process (see 902 of FIG. 9) may use a third masking layer for the etching of a top electrode, a self-aligned etch to form the spacers, and a fourth masking layer for etching a bottom electrode.

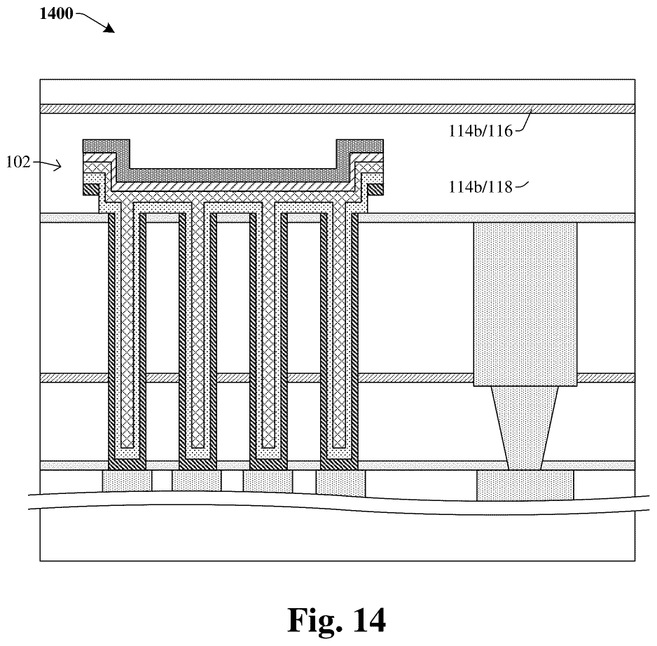

As shown in cross-sectional view 1400 of FIG. 14, a second portion 114b of the interlayer dielectric 114 is formed over the first plurality of capacitors 102 and the first portion of the interlayer dielectric 114. The second portion 114b comprising a second portion of the first plurality of insulative layers 118 and a second portion of the plurality of etch stop layers 116. In some embodiments, the second portion 114b of the interlayer dielectric 114 is formed using one or more deposition processes, such as ALD, PVD, CVD, or the like. In some embodiments, the second portion of the first plurality of insulative layers 118 is or comprises an insulative material such as silicon dioxide (SiO₂) or the like. In some embodiments, the second portion of the plurality of etch stop layers 116 is or comprises an insulative material such as silicon nitride (Si₃N₄), silicon carbide (SiC), or the like.

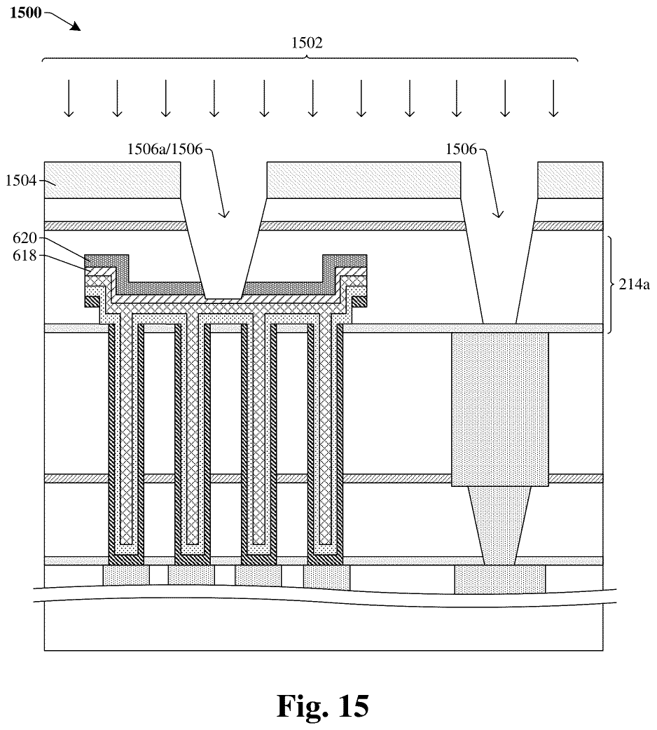

As shown in cross-sectional view 1500 of FIG. 15, a fourth masking layer 1504 is formed over the interlayer dielectric 114. In some embodiments, the fourth masking layer 1504 is or comprises a photoresist or a hard mask and is formed using a dipping process, spin on process, deposition process, or another similar process. The fourth masking layer 1504 is then patterned. In some embodiments, the fourth masking layer 1504 is patterned using photolithography. The patterning of the fourth masking layer 1504 is performed to expose portions of the interlayer dielectric 114 corresponding to vias (e.g., the first via (see 609 of FIG. 6A) of a via level 214a of the one or more via levels 214 to be formed hereafter.

After the patterning of the fourth masking layer 1504, a fourth etching process 1502 is performed. The fourth etching process 1502 removes portions of the interlayer dielectric 114 corresponding to vias (e.g., the first via (see 609 of FIG. 6A) of a via level 214a of the one or more via levels 214. The fourth etching process 1502 results in a plurality of via openings 1506 remaining in the interlayer dielectric, wherein the fourth etching process 1502 removes portions of the second capping layer 620 within a first via opening 1506a. In some embodiments, the fourth etching process 1502 removes portions of the first capping layer 618 within the first via opening 1506a. In some embodiments, the fourth etching process 1502 is or comprises an anisotropic dry etching process. The fourth masking layer 1504 is subsequently removed.

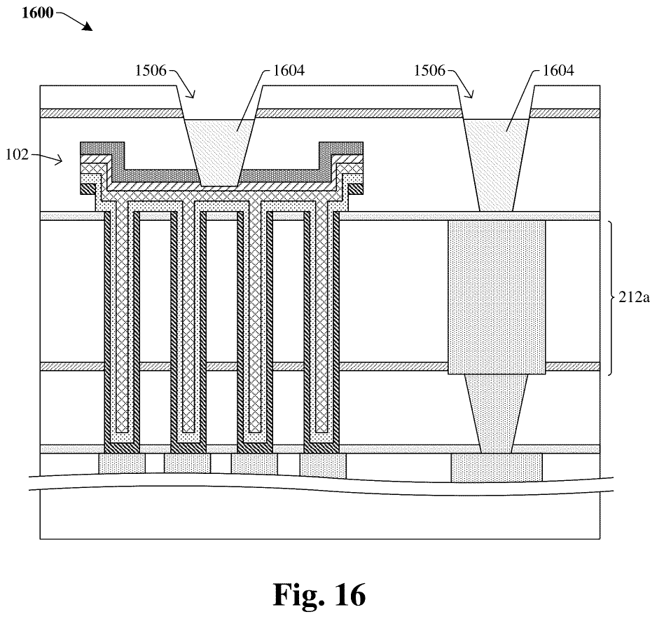

As shown in cross-sectional view 1600 of FIG. 16, a second plurality of photoresist plugs 1604 are formed in the plurality of via openings 1506. In some embodiments, the second plurality of photoresist plugs 1604 are formed using a spin on, spray on, dipping, or another similar process, and are patterned using one or more of photolithography or an etch back process. The second plurality of photoresist plugs 1604 protect the first plurality of capacitors 102 and wires of a wire level 212a from damage during subsequent etching processes.

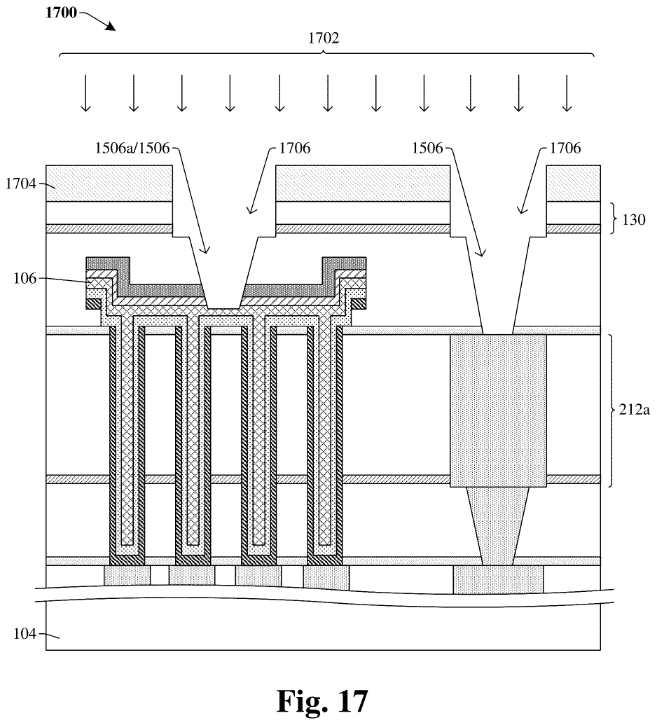

As shown in cross-sectional view 1700 of FIG. 17, a fifth masking layer 1704 is formed over the interlayer dielectric 114. In some embodiments, the fifth masking layer 1704 is or comprises a photoresist or a hard mask and is formed using a dipping process, spin on process, deposition process, or another similar process. The fifth masking layer 1704 is then patterned. In some embodiments, the fifth masking layer 1704 is patterned using photolithography. The patterning of the fifth masking layer 1704 is performed to expose portions of the interlayer dielectric 114 corresponding to wires (e.g., the first upper wire 128) of the upper wire level 130 to be formed hereafter.

After the patterning of the fifth masking layer 1704, a fifth etching process 1702 is performed. The fifth etching process 1702 removes portions of the interlayer dielectric 114 corresponding to wires (e.g., the first upper wire 128) of the upper wire level 130 and extends the via openings 1506 to the first shared top electrode 106 and the wire level 212a. The fifth etching process 1702 extends the plurality of via openings 1506 towards the substrate 104 and results in first wire openings 1706 being formed over the plurality of via openings 1506, wherein the first via opening 1506a extends to the first shared top electrode 106. In some embodiments, the fifth etching process 1702 is or comprises an anisotropic dry etching process. The fifth masking layer 1704 is subsequently removed, and remaining portions of the plurality of photoresist plugs (see 804 of FIG. 8) are removed using an ashing process or the like.

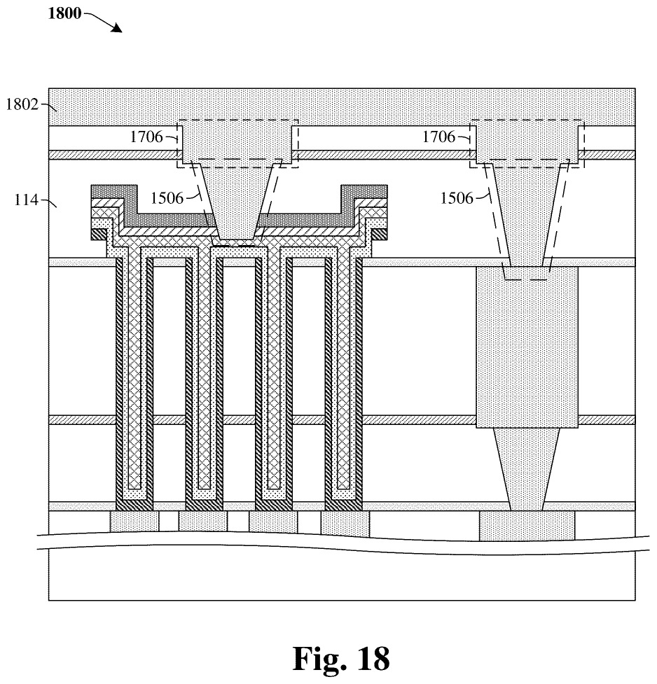

As shown in the cross-sectional view 1800 of FIG. 18, a conformal conductive layer 1802 is formed over the interlayer dielectric 114, filling the first via openings 1506 and the first wire openings 1706 (shown in phantom). In some embodiments, the conformal conductive layer 1802 is formed using a deposition process, such as ALD, PVD, CVD, or the like. In some embodiments, the conformal conductive layer 1802 is or comprises a conductive material, such as such as copper (Cu), tungsten (W), aluminum (Al), or the like.

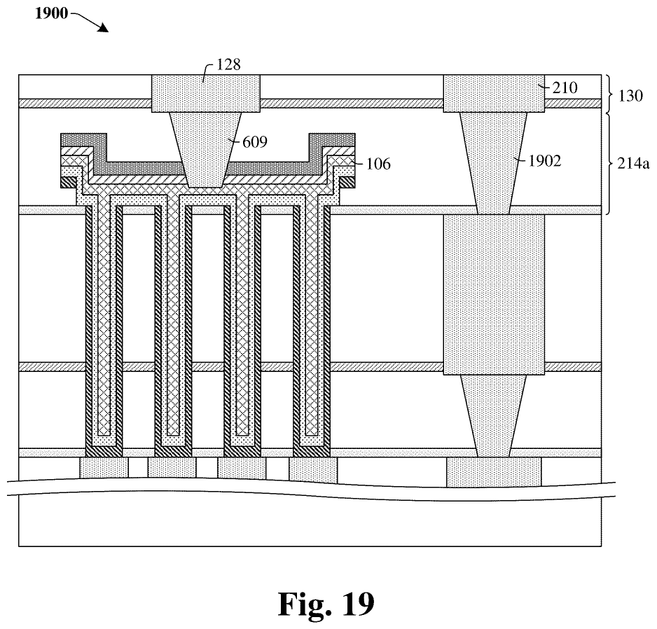

As shown in the cross-sectional view 1900 of FIG. 19, portions of the conformal conductive layer (see 1802 of FIG. 18) over the interlayer dielectric 114 are removed, resulting in the first upper wire 128, the second upper wire 210, the first via 609, and a third via 1902 remaining on the interlayer dielectric 114. The third via 1902 is in the via level 214a and is coupled to the second upper wire 210. The first via 609 electrically couples the first shared top electrode 106 to the first upper wire 128.

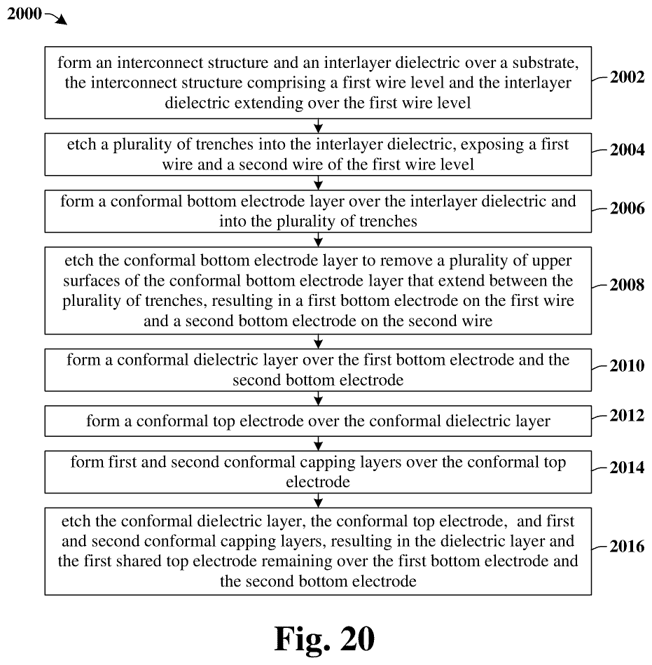

FIG. 20 illustrates a flow diagram 2000 of some embodiments of a method of forming an integrated device having a first plurality of capacitors comprising the shared top electrode. While method 2000 is illustrated and described below as a series of acts or events, it will be appreciated that the illustrated ordering of such acts or events are not to be interpreted in a limiting sense. For example, some acts may occur in different orders and/or concurrently with other acts or events apart from those illustrated and/or described herein. In addition, not all illustrated acts may be required to implement one or more aspects or embodiments of the description herein. Further, one or more of the acts depicted herein may be carried out in one or more separate acts and/or phases.

At 2002, an interconnect structure and an interlayer dielectric are formed over a substrate, the interconnect structure comprising a first wire level and the interlayer dielectric extending over the first wire level. FIG. 7 illustrates a cross-sectional view 700 of some embodiments corresponding to act 2002.

At 2004, a plurality of trenches are etched into the interlayer dielectric, exposing a first wire and a second wire of the first wire level. FIG. 7 illustrates a cross-sectional view 700 of some embodiments corresponding to act 2004.

At 2006, a first conformal electrode layer is formed over the interlayer dielectric and into the plurality of trenches. FIG. 8 illustrates a cross-sectional view 800 of some embodiments corresponding to act 2006.

At 2008, the first conformal electrode layer is etched to remove a plurality of upper surfaces of the first conformal electrode layer that extend between the plurality of trenches, resulting in a first bottom electrode on the first wire and a second bottom electrode on the second wire. FIG. 9 illustrates a cross-sectional view 900 of some embodiments corresponding to act 2008.

At 2010, a conformal dielectric layer is formed over the first bottom electrode and the second bottom electrode. FIG. 10 illustrates a cross-sectional view 1000 of some embodiments corresponding to act 2010.

At 2012, a second conformal electrode layer is formed over the conformal dielectric layer. FIG. 11 illustrates a cross-sectional view 1100 of some embodiments corresponding to act 2012.

At 2014, first and second conformal capping layers are formed over the second conformal electrode layer. FIG. 12 illustrates a cross-sectional view 1200 of some embodiments corresponding to act 2014.

At 2016, the conformal dielectric layer, the second conformal electrode layer, and first and second conformal capping layers are etched, resulting in the dielectric layer and the first shared top electrode remaining over the first bottom electrode and the second bottom electrode. FIG. 13 illustrates a cross-sectional view 1300 of some embodiments corresponding to act 2016.

Therefore, the present disclosure relates to an integrated device having a plurality of capacitors with a first shared top electrode to reduce the lateral footprint of the plurality of capacitors.

Accordingly, in some embodiments, the present disclosure relates to an integrated device, including: a first shared top electrode comprising a base portion extending over a substrate with a first width in a first direction and a first height in a second direction perpendicular to the first direction, wherein the first width is greater than the first height, and a plurality of protrusions extending beneath the base portion, the plurality of protrusions having a second width in the first direction and a second height in the second direction, wherein the second height is greater than the second width; a first bottom electrode surrounding a first protrusion of the plurality of protrusions in the first direction and a third direction perpendicular to the first direction and the second direction; a second bottom electrode surrounding a second protrusion of the plurality of protrusions in the first direction and the third direction; and a dielectric layer separating the first bottom electrode from the first shared top electrode and separating the second bottom electrode from the first shared top electrode.

In other embodiments, the present disclosure relates to a method of forming an integrated device, including: forming an interconnect structure over a substrate comprising a first wire level and an interlayer dielectric; etching a plurality of trenches into the interlayer dielectric, exposing a first wire and a second wire of the first wire level; forming a first conformal electrode layer over the interlayer dielectric and into the plurality of trenches; etching the first conformal electrode layer to remove a plurality of upper surfaces of the first conformal electrode layer that extend between the plurality of trenches, resulting in a first bottom electrode on the first wire and a second bottom electrode on the second wire; forming a conformal dielectric layer over the first bottom electrode and the second bottom electrode; forming a second conformal electrode layer over the conformal dielectric layer; and etching the conformal dielectric layer and the second conformal electrode layer, resulting in the dielectric layer and the first shared top electrode remaining over the first bottom electrode and the second bottom electrode.

In yet other embodiments, the present disclosure relates to a method of forming an integrated device, including: forming an interlayer dielectric over a substrate; etching a first plurality of trenches into the interlayer dielectric; forming a first conformal electrode layer over the interlayer dielectric and into the first plurality of trenches; etching the first conformal electrode layer to remove a plurality of upper surfaces of the first conformal electrode layer, resulting in a first bottom electrode remaining in a first trench of the plurality of trenches, a second bottom electrode remaining in a second trench of the plurality of trenches and spaced from the first bottom electrode, and an overlying portion of the first conformal electrode layer isolated from the first bottom electrode and the second bottom electrode; forming a conformal dielectric layer over the first bottom electrode and the second bottom electrode; forming a second conformal electrode layer over the conformal dielectric layer; and etching the conformal dielectric layer, the second conformal electrode layer, and the overlying portion of the first conformal electrode layer, resulting in the dielectric layer and the first shared top electrode remaining over the first bottom electrode, the second bottom electrode, and a first floating conductive ring.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated device, comprising:
a first top electrode comprising a base portion extending over a substrate with a first width in a first direction and a first height in a second direction perpendicular to the first direction, wherein the first width is greater than the first height, and a plurality of protrusions extending beneath the base portion, the plurality of protrusions having a second width in the first direction and a second height in the second direction, wherein the second height is greater than the second width;
a first bottom electrode surrounding a first protrusion of the plurality of protrusions in the first direction and a third direction perpendicular to the first direction and the second direction;
a second bottom electrode surrounding a second protrusion of the plurality of protrusions in the first direction and the third direction and separated from the first bottom electrode; and
a dielectric layer separating the first bottom electrode from the first top electrode and separating the second bottom electrode from the first top electrode.

2. The integrated device of claim 1, further comprising:
a first wire of a first wire level extending beneath the first bottom electrode and electrically coupled to the first bottom electrode;
a second wire of the first wire level extending beneath the second bottom electrode and electrically coupled to the second bottom electrode, wherein the second wire is electrically isolated from to the first wire by an interlayer dielectric;
a third wire of a second wire level that electrically couples the first top electrode to a voltage rail;
a first pixel circuit comprising a first plurality of photodetectors, a first floating diffusion region, a first plurality of transfer transistors with first source/drain regions coupled to the first plurality of photodetectors and second source/drain regions coupled to the first floating diffusion region, a first source/follower transistor, and a first row select transistor;
a second pixel circuit comprising a second plurality of photodetectors, a second floating diffusion region, a second plurality of transfer transistors with third source/drain regions coupled to the second plurality of photodetectors and fourth source/drain regions coupled to the second floating diffusion region, a second source/follower transistor, and a second row select transistor;
a first lateral overflow integration capacitor (LOFIC) transistor comprising a fifth source/drain region coupled to the first wire and a sixth source/drain region coupled to the first floating diffusion region; and
a second LOFIC transistor comprising a seventh source/drain region coupled to the second wire and a eighth source/drain region coupled to the second floating diffusion region.

3. The integrated device of claim 1, further comprising:
a first wire of a first wire level extending beneath the first bottom electrode and electrically coupled to the first bottom electrode;
a second wire of the first wire level extending beneath the second bottom electrode and electrically coupled to the second bottom electrode, wherein the second wire is electrically isolated from to the first wire by an interlayer dielectric;
a third wire of a second wire level that electrically couples the first top electrode to a voltage rail; and
an correlated double sampling circuit, comprising:
a comparator having a first input and a second input;
a first sampling transistor having a first source/drain region coupled to the first wire and the first input and a second source/drain region coupled to an output line; and
a second sampling transistor having a third source/drain region coupled to the second wire and the second input and a fourth source/drain region coupled to the output line.

4. The integrated device of claim 1, further comprising a first wire of a first wire level extending beneath the first bottom electrode and the second bottom electrode and electrically coupling the first bottom electrode to the second bottom electrode.

5. The integrated device of claim 4, further comprising:
a third bottom electrode surrounding a third protrusion of the plurality of protrusions in the first direction and the third direction; and
a second wire of the first wire level extending beneath the third bottom electrode and electrically coupled to the third bottom electrode, wherein the second wire is electrically isolated from to the first wire by an interlayer dielectric.

6. The integrated device of claim 5, further comprising:
a third wire of a second wire level that electrically couples the first top electrode to a voltage rail;
an pixel circuit, comprising:
a plurality of photodetectors;
a floating diffusion region;
a plurality of transfer transistors extending between the plurality of photodetectors and the floating diffusion region;
a source follower transistor having a gate coupled to the floating diffusion region;
a medium conversion gain transistor having a first source/drain region coupled to the second wire and a second source/drain region coupled to the floating diffusion region; and
a low conversion gain transistor having a third source/drain region coupled to the first wire and a fourth source/drain region coupled to the second wire.

7. A method of forming an integrated device, comprising:
forming an interconnect structure and an interlayer dielectric over a substrate, the interconnect structure comprising a first wire level;
etching a plurality of trenches into the interlayer dielectric, exposing a first wire and a second wire of the first wire level;
forming a first conformal electrode layer over the interlayer dielectric and into the plurality of trenches;
etching the first conformal electrode layer to remove a plurality of upper surfaces of the first conformal electrode layer that extend between the plurality of trenches, resulting in a first bottom electrode on the first wire and a second bottom electrode on the second wire;
forming a conformal dielectric layer over the first bottom electrode and the second bottom electrode;
forming a second conformal electrode layer over the conformal dielectric layer; and
etching the conformal dielectric layer and the second conformal electrode layer, resulting in a dielectric layer and a first top electrode remaining over the first bottom electrode and the second bottom electrode.

8. The method of claim 7, wherein etching the conformal dielectric layer and the second conformal electrode layer further removes portions of the first conformal electrode layer remaining over the substrate, resulting in a floating conductive ring surrounding the first bottom electrode and the second bottom electrode.

9. The method of claim 7, wherein etching the first conformal electrode layer exposes an etch stop layer within the interlayer dielectric, wherein the etch stop layer extends between upper surfaces of the first bottom electrode and the second bottom electrode.

10. The method of claim 7, further comprising forming a second wire level comprising a third wire over the first top electrode and coupled to the first top electrode.

11. The method of claim 7, wherein after etching the second conformal electrode layer, a base portion of the first top electrode extends directly over the first bottom electrode and the second bottom electrode, a first protrusion of the first top electrode extends directly between inner sidewalls of the first bottom electrode, and a second protrusion of the first top electrode extends directly between inner sidewalls of the second bottom electrode.

12. The method of claim 7, wherein etching the first conformal electrode layer further comprises:
forming first photoresist plugs between inner sidewalls of the first conformal electrode layer;
forming a masking layer overlying the interlayer dielectric and surrounding the plurality of trenches, wherein the masking layer is spaced from the plurality of trenches in a first direction parallel to a surface of the substrate and a second direction parallel to the surface of the substrate and perpendicular to the first direction; and
performing an etching process to remove portions of the first conformal electrode layer and the interlayer dielectric exposed by the masking layer and the first photoresist plugs, thereby separating the first bottom electrode, the second bottom electrode, and portions of the first conformal electrode layer remaining on the interlayer dielectric.

13. A method of forming an integrated device, comprising:
forming an interlayer dielectric over a substrate;
etching a first plurality of trenches into the interlayer dielectric;
forming a first conformal electrode layer over the interlayer dielectric and into the first plurality of trenches;
etching the first conformal electrode layer to remove a plurality of upper surfaces of the first conformal electrode layer, resulting in a first bottom electrode remaining in a first trench of the first plurality of trenches, a second bottom electrode remaining in a second trench of the first plurality of trenches and spaced from the first bottom electrode, and an overlying portion of the first conformal electrode layer isolated from the first bottom electrode and the second bottom electrode;
forming a conformal dielectric layer over the first bottom electrode and the second bottom electrode;
forming a second conformal electrode layer over the conformal dielectric layer; and
etching the conformal dielectric layer, the second conformal electrode layer, and the overlying portion of the first conformal electrode layer, resulting in a dielectric layer and a first top electrode remaining over the first bottom electrode, the second bottom electrode, and a first floating conductive ring.

14. The method of claim 13, wherein a second plurality of trenches are etched concurrently with the etching of the first plurality of trenches,
wherein etching the first conformal electrode layer further results in a third bottom electrode being formed in a trench of the second plurality of trenches, and
wherein the third bottom electrode is separated from the first bottom electrode and the second bottom electrode by the overlying portion of the first conformal electrode layer.

15. The method of claim 14, wherein etching the overlying portion of the first conformal electrode layer further results in a second floating conductive ring surrounding the third bottom electrode and spaced from the first floating conductive ring.

16. The method of claim 13, further comprising forming a second portion of the interlayer dielectric over the first top electrode, the dielectric layer, and the first floating conductive ring, wherein outer sidewalls of the first floating conductive ring, the dielectric layer, and the first top electrode contact an inner sidewall of the second portion of the interlayer dielectric.

17. The method of claim 13, further comprising forming a capping layer over the second conformal electrode layer, wherein the capping layer is etched during a same etching process as the conformal dielectric layer, the second conformal electrode layer, and the overlying portion of the first conformal electrode layer.

18. The method of claim 13, wherein after etching the overlying portion of the first conformal electrode layer, the first floating conductive ring is spaced from the first bottom electrode and the second bottom electrode in a direction normal to a bottom surface of the first floating conductive ring.

19. The method of claim 13, wherein after forming the conformal dielectric layer, the conformal dielectric layer extends from the first bottom electrode to the overlying portion of the first conformal electrode layer.

20. The method of claim 13, wherein after forming the conformal dielectric layer, the conformal dielectric layer directly contacts inner sidewalls of the interlayer dielectric.
